(19) United States
(12) Patent Application Publication
(10) Pub. No.: US 2025/0120134 A1
(43) Pub. Date: Apr. 10, 2025

(54) SEMICONDUCTOR DEVICE

(71) Applicant: Mitsubishi Electric Corporation, Tokyo (JP)

(72) Inventor: Manabu YOSHINO, Tokyo (JP)

(73) Assignee: Mitsubishi Electric Corporation, Tokyo (JP)

(21) Appl. No.: 18/764,478

(22) Filed: Jul. 5, 2024

(30) Foreign Application Priority Data
Oct. 4, 2023 (JP) 2023-172800

(51) Int. Cl. H01L 29/06; H01L 27/12

(52) U.S. Cl. CPC H10D 62/109; H10D 86/201

(57) ABSTRACT

In a semiconductor device, a first N-type diffusion layer is provided in a first high-side circuit region, and a second N-type diffusion layer is provided in a second high-side circuit region. Constituent elements for first and second high-side circuits are provided in the first and second N-type diffusion layers. An isolation trench is provided between the first N-type diffusion layer and the second N-type diffusion layer. The deepest portion of the isolation trench reaches a P-type substrate region of a P-type substrate. The first N-type diffusion layer and the second N-type diffusion layer are electrically isolated by the isolation trench having a buried insulating film inside.

### BACKGROUND OF THE INVENTION

### Field of the Invention

The present disclosure relates to a semiconductor device having a high-side circuit region and a low-side circuit region.

### Description of the Background Art

A high voltage integrated circuit (HVIC) for power control, which is mainly used for driving a gate of a power semiconductor device, generally includes a low-side circuit that operates with a ground (GND) potential as a reference potential, a high-side circuit that operates with a potential different from the GND potential, such as a floating potential, as a reference potential, and a level shift circuit that performs signal transmission between the low-side circuit and the high-side circuit.

As a conventional HVIC, for example, there is a semiconductor device disclosed in Japanese Patent No. 7001050. In the semiconductor device having an HVIC configuration disclosed in Japanese Patent No. 7001050, a high breakdown voltage termination structure in a high-side circuit region provided with a high-side circuit and a high breakdown voltage level shift element are electrically isolated by trench isolation.

In the conventional semiconductor device having the HVIC configuration, the high breakdown voltage termination structure of the high-side circuit region and the high breakdown voltage level shift can be isolated from each other, but an internal configuration of the high-side circuit region is generally a configuration in which elements are provided in the same N-type diffusion region, so that a power supply voltage of the high-side circuit region becomes a single power supply voltage. In addition, even in a case where a plurality of high-side circuits operating at different power supply voltages are provided in the high-side circuit region, it is necessary to design an element breakdown voltage as a breakdown voltage of the maximum voltage in the circuits, and thus, there is a problem that the device is increased in size.

As described above, the conventional semiconductor device having the HVIC configuration has a problem that the plurality of high-side circuits operating at different power supply voltages cannot be provided in the high-side circuit region without increasing the size of the device.

### SUMMARY

The present disclosure has been made to solve the above-described problem, and an object thereof is to obtain a semiconductor device including a high-side circuit region provided with a plurality of high-side circuits operating at a plurality of different power supply voltages without increasing a size of the device.

A semiconductor device according to the present disclosure includes a semiconductor substrate, a low-side circuit region, a high-side circuit region, and a first isolation region.

The low-side circuit region is provided in the semiconductor substrate and receives a first reference potential.

The high-side circuit region is provided in the semiconductor substrate and receives a second reference potential different from the first reference potential.

The first isolation region electrically isolates the low-side circuit region from the high-side circuit region.

The semiconductor substrate has a circuit base region in which the low-side circuit region and the high-side circuit region are not provided.

The high-side circuit region includes first and second high-side circuit regions. A first high-side circuit is provided in the first high-side circuit region, and a second high-side circuit is provided in the second high-side circuit region.

The first high-side circuit operates at a first power supply voltage based on the second reference potential, and the second high-side circuit operates at a second power supply voltage based on the second reference potential. The first and second power supply voltages have different voltage values.

The semiconductor device further includes a second isolation region that electrically isolates the first high-side circuit region and the second high-side circuit region.

Since the semiconductor device of the present disclosure has the second isolation region that electrically isolates the first and second high-side circuit regions from each other, there is no trouble even if the first high-side circuit provided in the first high-side circuit region is operated at the first power supply voltage and the second high-side circuit provided in the second high-side circuit region is operated at the second power supply voltage different from the first power supply voltage.

Therefore, in the semiconductor device of the present disclosure, the first and second high-side circuit regions having the first and second high-side circuits can be provided in the high-side circuit region with a structure maintaining miniaturization.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is an explanatory diagram schematically illustrating a planar configuration of a semiconductor device of a first preferred embodiment;

FIG. 2 is an explanatory diagram schematically illustrating a circuit configuration of the semiconductor device illustrated in FIG. 1;

FIG. 3 is a cross-sectional view illustrating a cross section of a semiconductor device as a first aspect of the first preferred embodiment;

FIG. 4 is a cross-sectional view illustrating a cross section of a semiconductor device as a second aspect of the first preferred embodiment;

FIG. 5 is a cross-sectional view illustrating a cross section of a semiconductor device as a third aspect of the first preferred embodiment;

FIG. 6 is a cross-sectional view illustrating a cross section of a semiconductor device as a first aspect of a second preferred embodiment;

FIG. 7 is a cross-sectional view illustrating a cross section of a semiconductor device as a second aspect of the second preferred embodiment;

FIG. 8 is a cross-sectional view illustrating a cross section of a semiconductor device as a third aspect of the second preferred embodiment;

FIG. 9 is a cross-sectional view illustrating a cross section of a semiconductor device as a first aspect of a third preferred embodiment;

FIG. 10 is a cross-sectional view illustrating a cross section of a semiconductor device as a second aspect of the third preferred embodiment;

FIG. 11 is a cross-sectional view illustrating a cross section of a semiconductor device as a first aspect of a fourth preferred embodiment; and

FIG. 12 is a cross-sectional view illustrating a cross section of a semiconductor device as a second aspect of the fourth preferred embodiment.

### DESCRIPTION OF THE PREFERRED EMBODIMENTS

### First Preferred Embodiment

### (Planar Configuration and Circuit Configuration)

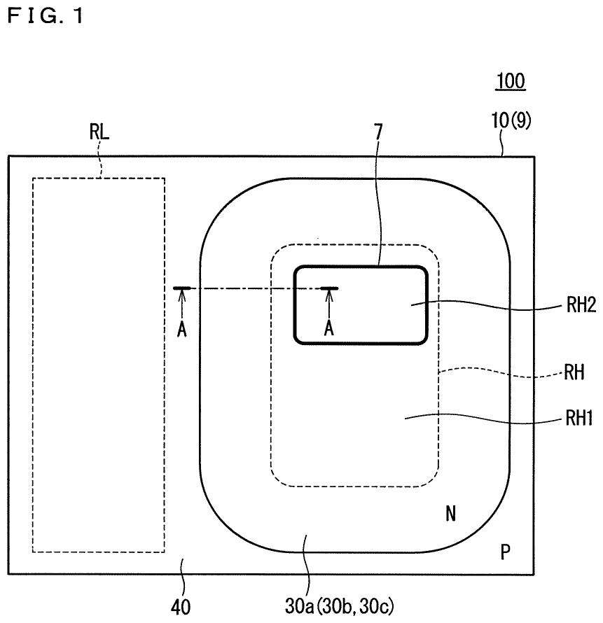

FIG. 1 is an explanatory diagram schematically illustrating a planar configuration of a semiconductor device 100 of a first preferred embodiment of the present disclosure. The semiconductor device 100 is used as a general term including semiconductor devices 101 to 108 and semiconductor devices 201 and 202. Note that the semiconductor devices 102 to 108, 201, and 202 will be described in detail later. That is, a structure illustrated in FIG. 1 is a planar structure common among the semiconductor devices 101 to 108 and the semiconductor devices 201 and 202 illustrated in the first to fourth preferred embodiments.

As illustrated in FIG. 1, an N-type diffusion layer 30a is provided on the outer periphery of a high-side circuit region RH, and a P-type diffusion layer 40 is provided surrounding the periphery of the N-type diffusion layer 30a in plan view. A combination of the N-type diffusion layer 30a and the P-type diffusion layer 40 serves as a first isolation region. A low-side circuit region RL and the high-side circuit region RH are electrically isolated by the N-type diffusion layer 30a and the P-type diffusion layer 40 which serve as the first isolation region. Therefore, each of the N-type diffusion layer 30a and the P-type diffusion layer 40 serves as a first isolation diffusion region included in the first isolation region. In the present specification, a P type is indicated as a first conductivity type, and an N type is indicated as a second conductivity type.

The high-side circuit region RH includes a first high-side circuit region RH1 and a second high-side circuit region RH2. A first high-side circuit CH1 is provided in the first high-side circuit region RH1, and a second high-side circuit CH2 is provided in the second high-side circuit region RH2.

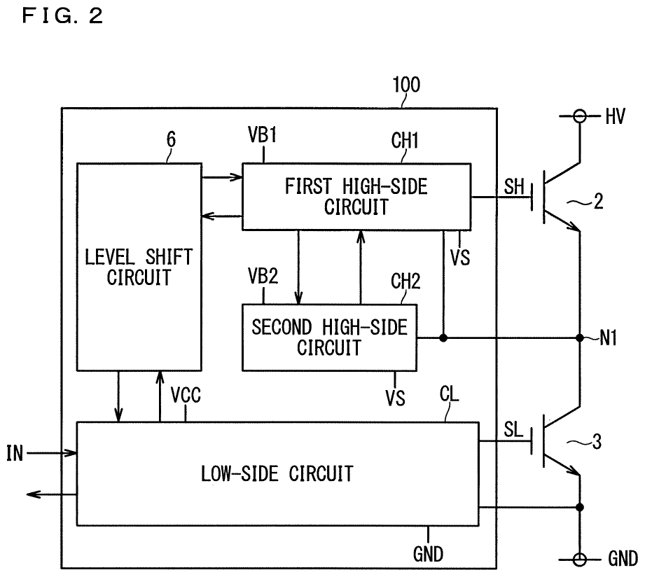

FIG. 2 is an explanatory diagram schematically illustrating a circuit configuration of the semiconductor device 100. As illustrated in the drawing, the circuit configuration of the semiconductor device 100 includes a low-side circuit CL, the first high-side circuit CH1, the second high-side circuit CH2, and a level shift circuit 6 as main components.

As described above, the low-side circuit CL is a circuit provided in the low-side circuit region RL, the first high-side circuit CH1 is a circuit provided in the first high-side circuit region RH1, and the second high-side circuit CH2 is a circuit provided in the second high-side circuit region RH2.

The low-side circuit CL receives a ground potential GND as a reference potential, and receives a low-side power supply voltage VCC as an operating voltage with the ground potential GND as the reference potential. The ground potential GND is a first reference potential for the low-side circuit CL. Therefore, the low-side circuit CL executes a circuit operation at the low-side power supply voltage VCC based on the ground potential GND. The level shift circuit 6 performs signal transmission between the low-side circuit CL and the first high-side circuit region RH1.

The first high-side circuit CH1 receives a high-side reference potential VS as a reference potential, and receives a high-side power supply voltage VB1 as an operating voltage. Therefore, the first high-side circuit CH1 executes a circuit operation at the high-side power supply voltage VB1 based on the high-side reference potential VS.

The second high-side circuit CH2 receives the high-side reference potential VS as a reference potential, and receives a high-side power supply voltage VB2 as an operating voltage. Therefore, the second high-side circuit CH2 executes a circuit operation at the high-side power supply voltage VB2 based on the high-side reference potential VS. The high-side power supply voltage VB2 is set to a voltage value different from that of the high-side power supply voltage VB1.

The high-side reference potential VS becomes a second reference potential common between the first and second high-side circuits CH1 and CH2. The high-side reference potential VS is a potential different from the ground potential GND, and is electrically isolated from the ground potential GND, and thus, is normally floating.

As described above, the first high-side circuit CH1 executes the circuit operation with the high-side power supply voltage VB1 as the operating voltage, and the second high-side circuit CH2 executes the circuit operation with the high-side power supply voltage VB2 as the operating voltage.

The high-side power supply voltage VB1 received by the first high-side circuit CH1 is a first power supply voltage, and the high-side power supply voltage VB2 received by the second high-side circuit CH2 is a second power supply voltage. As described above, the high-side power supply voltage VB1 as the first power supply voltage and the high-side power supply voltage VB2 as the second power supply voltage are set to voltage levels different from each other.

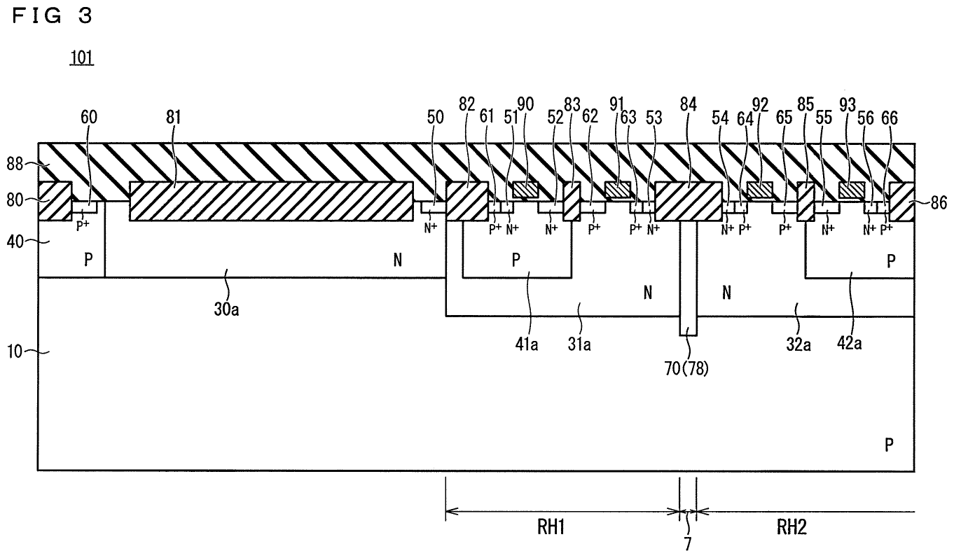

FIG. 1 mainly illustrates a top view of the periphery of the high-side circuit region RH in the semiconductor device 100. In FIG. 1, description regarding diffusion layers corresponding to a cross-sectional structure of FIG. 3 and the like, which will be described below, is partially omitted. In addition, a high breakdown voltage MOS used as the level shift circuit 6 illustrated in FIG. 2 is not illustrated.

As illustrated in FIG. 1, in the high-side circuit region RH, an isolation region 7 is provided on the outer periphery of the second high-side circuit region RH2. The first high-side circuit region RH1 and the second high-side circuit region RH2 are electrically isolated by the isolation region 7.

The semiconductor device 100 illustrated in FIG. 2 controls an IGBT 2 and an IGBT 3 connected in series. A collector of the IGBT 2 receives a high voltage HV, an emitter of the IGBT 2 and a collector of the IGBT 3 are connected at a node N1, and an emitter of the IGBT 3 is set to the ground potential GND.

The low-side circuit CL receives an input signal IN from the outside and outputs a low-side control signal SL to a gate of the IGBT 3. In addition, the first high-side circuit CH1 outputs a high-side control signal SH to a gate of the IGBT 2. A signal obtained at the node N1 is given to each of the first and second high-side circuits CH1 and CH2. In addition, a signal is transmitted and received between the first and second high-side circuits CH1 and CH2.

The low-side circuit region RL and the high-side circuit region RH are isolated with a high breakdown voltage of 100 V or more by the N-type diffusion layer 30a and the P-type diffusion layer 40 each serving as the first isolation diffusion region. The low-side circuit region RL and the high-side circuit region RH are isolated by a RESURF isolation structure using the N-type diffusion layer 30a as a diffusion layer of the N type that is the second conductivity type.

As described above, the low-side circuit region RL and the high-side circuit region RH are isolated from each other by the N-type diffusion layer 30a and the P-type diffusion layer 40 each serving as the first isolation diffusion region such that there is no trouble even if a voltage difference between the low-side circuit region RL and the high-side circuit region RH is 100 V or more.

The isolation region 7, which serves as a second isolation region, isolates the first high-side circuit region RH1 and the second high-side circuit region RH2 from each other with a breakdown voltage at a level of several tens V. The high breakdown voltage MOS not illustrated in FIG. 1 is provided in the N-type diffusion layer 30a or the low-side circuit region RL.

As described above, the first and second high-side circuit regions RH1 and RH2 are isolated from each other by the isolation region 7 serving as the second isolation region such that there is no trouble if a voltage difference between the first high-side circuit region RH1 and the second high-side circuit region RH2 is about 10 V.

### (First Aspect)

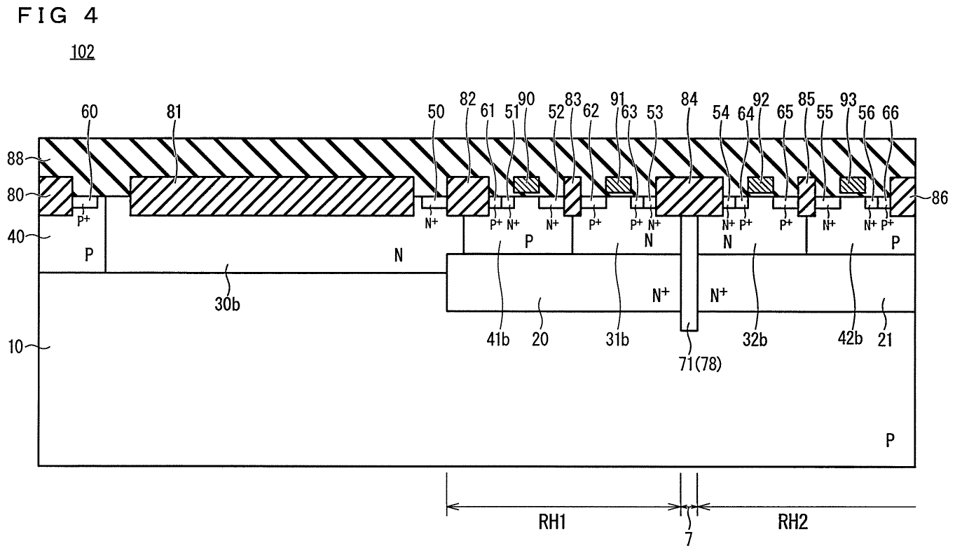

FIG. 3 is a cross-sectional view schematically illustrating a cross-sectional structure of the semiconductor device 101 as a first aspect of the first preferred embodiment. FIG. 3 illustrates a cross-sectional structure corresponding to an A-A cross section of FIG. 1. The cross-sectional structure in FIG. 3 and cross-sectional structures in FIGS. 4 to 12 to be described below are schematically illustrated, and the shape, scale, and the like do not necessarily match those of cross-sectional structures to be actually manufactured.

As illustrated in FIG. 3, the first and second high-side circuit regions RH1 and RH2 are provided in an upper layer portion of a P-type substrate 10 which is a semiconductor substrate of the first conductivity type. As illustrated in FIG. 3, as the first isolation region for isolating the high-side circuit region RH and the low-side circuit region RL, the N-type diffusion layer 30a and the P-type diffusion layer 40 are provided in the upper layer portion of the P-type substrate 10. The P-type diffusion layer 40 is provided so as to surround the high-side circuit region RH in plan view. The N-type diffusion layer 30a satisfies a RESURF condition.

A P⁺ diffusion layer 60 is provided in a part of a surface of the P-type diffusion layer 40. The P⁺ diffusion layer 60 is a layer for making contact between the P-type diffusion layer 40 and a metal wiring layer (not illustrated in FIG. 3). An N⁺ diffusion layer 50 is provided in a part of a surface of the N-type diffusion layer 30a. The N⁺ diffusion layer 50 is a layer for making contact between the N-type diffusion layer 30a and the metal wiring layer (not illustrated in FIG. 3). The N⁺ diffusion layer 50 is provided at a position separated from the P-type diffusion layer 40 by a certain distance of several tens um or more in the surface of the N-type diffusion layer 30a.

A thermal oxide film 81 is provided on the surface of the N-type diffusion layer 30a between the P-type diffusion layer 40 and the N⁺ diffusion layer 50. A field plate including polysilicon or a metal wiring layer is provided on the thermal oxide film 81. Note that the field plate is not illustrated in FIG. 3 for simplification of the drawing. The field plate may be provided across end portions of the thermal oxide film 81.

An N-type diffusion layer 31a is provided in the upper layer portion of the P-type substrate 10, which is the semiconductor substrate of the first conductivity type, in the first high-side circuit region RH1, and an N-type diffusion layer 32a is provided in the upper layer portion of the P-type substrate 10 in the second high-side circuit region RH2.

The N-type diffusion layer 31a and the N-type diffusion layer 32a are formed at the same time, and the N-type diffusion layer 30a is formed after the formation of the N-type diffusion layers 31a and 32a. A formation depth of each of the N-type diffusion layers 31a and 32a is deeper than a diffusion depth of the N-type diffusion layer 30a as the first isolation diffusion region. The N-type diffusion layer 31a serves as a first circuit diffusion region, and the N-type diffusion layer 32a serves as a second circuit diffusion region. Therefore, the N-type diffusion layers 31a and 32a respectively serving as the first and second circuit diffusion regions satisfy a diffusion region depth requirement that “a formation depth of each of the first and second circuit diffusion regions is deeper than a formation depth of the first isolation diffusion region”.

A constituent element of the first high-side circuit CH1 is provided in an upper layer portion of the N-type diffusion layer 31a, and a constituent element of the second high-side circuit CH2 is provided in an upper layer portion of the N-type diffusion layer 32a. FIG. 3 illustrates a case where, for example, CMOS configurations are provided as the constituent elements.

In the first high-side circuit region RH1, a P-type diffusion layer 41a is selectively provided in the upper layer portion of the N-type diffusion layer 31a, N⁺ diffusion layers 51 and 52 are selectively provided in a surface of the P-type diffusion layer 41a, and the N⁺ diffusion layers 51 and 52 are provided at a certain interval of 0.1 μm or more. A polysilicon gate 90 is provided above the P-type diffusion layer 41a between the N⁺ diffusion layers 51 and 52 with a gate oxide film (not illustrated) interposed therebetween. Further, a P⁺ diffusion layer 61 is provided in a part of the surface of the P-type diffusion layer 41a, and the P⁺ diffusion layer 61 is a layer for making contact between the P-type diffusion layer 41a and the metal wiring layer (not illustrated in FIG. 3), and is provided to be adjacent to the N⁺ diffusion layer 51.

Therefore, the P-type diffusion layer 41a and the N⁺ diffusion layers 51 and 52 provided in the upper layer portion of the N-type diffusion layer 31a, the gate oxide film, and the polysilicon gate 90 constitute an NMOS transistor as a constituent element for the first high-side circuit CH1.

In the first high-side circuit region RH1, P⁺ diffusion layers 62 and 63 are selectively provided in the surface of the N-type diffusion layer 31a, and the P⁺ diffusion layers 62 and 63 are provided at a certain interval of 0.1 μm or more. A polysilicon gate 91 is provided above the N-type diffusion layer 31a between the P⁺ diffusion layers 62 and 63 with a gate oxide film (not illustrated) interposed therebetween. Further, an N⁺ diffusion layer 53 is provided in a part of the surface of the N-type diffusion layer 31a. The N⁺ diffusion layer 53 is a layer for making contact between the N-type diffusion layer 31a and the metal wiring layer (not illustrated in FIG. 3), and is provided to be adjacent to the P⁺ diffusion layer 63.

Therefore, the P⁺ diffusion layers 62 and 63 provided in the upper layer portion of the N-type diffusion layer 31a, the gate oxide film, and the polysilicon gate 91 constitute a PMOS transistor as a constituent element for the first high-side circuit CH1.

A combination structure of the NMOS transistor and the PMOS transistor described above is a CMOS configuration provided in the first high-side circuit region RH1. The first high-side circuit CHI has this CMOS configuration.

On the other hand, in the second high-side circuit region RH2, a P-type diffusion layer 42a is selectively provided in the upper layer portion of the N-type diffusion layer 32a, N⁺ diffusion layers 55 and 56 are selectively provided in the surface of the P-type diffusion layer 42a, and the N⁺ diffusion layers 55 and 56 are provided at a certain interval of 0.1 μm or more. A polysilicon gate 93 is provided above the P-type diffusion layer 42a between the N⁺ diffusion layers 55 and 56 with a gate oxide film (not illustrated) interposed therebetween. Further, a P⁺ diffusion layer 66 is provided in a part of the surface of the P-type diffusion layer 42a. The P⁺ diffusion layer 66 is a layer for making contact between the P-type diffusion layer 42a and the metal wiring layer (not illustrated in FIG. 3), and is provided to be adjacent to the N⁺ diffusion layer 56.

Therefore, the P-type diffusion layer 42a and the N⁺ diffusion layers 55 and 56 provided in the upper layer portion of the N-type diffusion layer 32a, the gate oxide film, and the polysilicon gate 93 constitute an NMOS transistor as a constituent element for the second high-side circuit CH2.

In the second high-side circuit region RH2, P⁺ diffusion layers 64 and 65 are selectively provided in the surface of the N-type diffusion layer 32a, and the P⁺ diffusion layers 64 and 65 are provided at a certain interval of 0.1 μm or more. A polysilicon gate 92 is provided above the N-type diffusion layer 32a between the P⁺ diffusion layers 64 and 65 with a gate oxide film (not illustrated) interposed therebetween. Further, an N⁺ diffusion layer 54 is provided in a part of the surface of the N-type diffusion layer 32a. The N⁺ diffusion layer 54 is a layer for making contact between the N-type diffusion layer 32a and the metal wiring layer (not illustrated in FIG. 3), and is provided to be adjacent to the P⁺ diffusion layer 64.

Therefore, the P⁺ diffusion layers 64 and 65 provided in the upper layer portion of the N-type diffusion layer 32a, the gate oxide film, and the polysilicon gate 92 constitute a PMOS transistor as a constituent element for the second high-side circuit CH2.

A combination structure of the NMOS transistor and the PMOS transistor described above is a CMOS configuration provided in the second high-side circuit region RH2. The second high-side circuit CH2 has this CMOS configuration.

In FIG. 3, each of the N⁺ diffusion layers 51, 52, 55, and 56 and the P⁺ diffusion layer 62 to 65 serving as a drain or a source of the MOS transistor having the CMOS configuration, is formed as a single drain structure. In consideration of a breakdown voltage between the drain and the source, a double diffused drain (DDD) structure or a lightly doped drain (LDD) structure may be adopted instead of the single drain structure.

In the P-type substrate 10, a region where the first and second high-side circuits CH1 and CH2 are not provided is a circuit base region. The first high-side circuit CH1 is provided in the N-type diffusion layer 31a and on the N-type diffusion layer 31a, and the second high-side circuit CH2 is provided in the N-type diffusion layer 32a and on the N-type diffusion layer 32a.

In the first preferred embodiment, a substrate region of the P type, which is the first conductivity type in the P-type substrate 10 and is present below the P-type diffusion layer 40, the N-type diffusion layer 30a, the N-type diffusion layer 31a, and the N-type diffusion layer 32a is the circuit base region. Note that the P-type substrate region in the P-type substrate 10 is set to the ground potential GND which is the first reference potential.

In the semiconductor device 101, an isolation trench 70 is provided in the isolation region 7. The isolation trench 70 is provided between the N-type diffusion layer 31a serving as the first circuit diffusion region and the N-type diffusion layer 32a serving as the second circuit diffusion region, and is provided such that the deepest portion reaches the P-type substrate region of the P-type substrate 10.

The N-type diffusion layer 31a and the N-type diffusion layer 32a are electrically isolated by the isolation trench 70. The isolation trench 70 is formed as follows, for example.

A provisional N-type diffusion layer is formed in an upper layer portion including the first and second high-side circuit regions RH1 and RH2 and the isolation region 7 in the P-type substrate 10, and thereafter, the isolation trench 70 is formed so as to reach the substrate region from the surface of the P-type substrate 10 including the provisional N-type diffusion layer in the isolation region 7. The provisional N-type diffusion layer is isolated between the first and second high-side circuit regions RH1 and RH2 by the isolation trench 70 formed in this manner.

In the present specification, “provisional” is used as a term indicating a structure in an intermediate stage that is not a completion stage.

As a result, the provisional N-type diffusion layer remaining in the first high-side circuit region RH1 serves as the N-type diffusion layer 31a, and the provisional N-type diffusion layer remaining in the second high-side circuit region RH2 serves as the N-type diffusion layer 32a. Therefore, the N-type diffusion layer 31a and the N-type diffusion layer 32a are electrically isolated by the isolation trench 70.

The isolation trench 70 includes a buried insulating film 78, configured to

insulate and isolate the first and second high-side circuit regions RH1 and RH2 from each other, inside. As a burying aspect of the buried insulating film 78, first and second burying aspects are conceivable. The first burying aspect is an aspect in which the isolation trench 70 is filled with the buried insulating film 78. The second burying aspect is an aspect in which the buried insulating film 78 is selectively formed on a sidewall in the isolation trench 70, and polysilicon (not illustrated) is filled in the isolation trench 70 including the buried insulating film 78.

Note that a formation depth of the isolation trench 70 is set to, for example, about several μm to 20 μm, and a formation width thereof is set to, for example, 1 to 2 μm. The term “several μm” means 2 to 3 μm.

In a case where the buried insulating film 78 is provided in the first burying aspect, a breakdown voltage between the first and second high-side circuit regions RH1 and RH2 is secured by an insulation breakdown voltage of the buried insulating film 78 with which the isolation trench 70 has been filled. In this case, a film thickness of the buried insulating film 78 corresponds to the formation width of the isolation trench 70. In a case where the buried insulating film 78 is provided in the second burying aspect, the breakdown voltage between the first and second high-side circuit regions RH1 and RH2 is secured by the insulation breakdown voltage of the buried insulating film 78 provided on the sidewall of the isolation trench 70.

The high-side power supply voltage VB1 is applied to the N-type diffusion layer 31a as the first circuit diffusion region via the N⁺ diffusion layer 53, and the high-side power supply voltage VB2 is applied to the N-type diffusion layer 32a as the second circuit diffusion region via the N⁺ diffusion layer 54. The high-side power supply voltages VB1 and VB2 are both high voltages of 100 V or more, and a potential difference between the high-side power supply voltage VB1 and the high-side power supply voltage VB2 is several V to several tens V.

An insulating layer 88 is provided so as to cover the entire surface of the semiconductor device 101. A metal wiring layer is provided on the insulating layer 88, and the metal wiring layer is individually connected to each of the N⁺ diffusion layers 50 to 56, the P⁺ diffusion layers 60 to 66, and the polysilicon gates 90 to 93 through a contact hole provided to penetrate the insulating layer 88. Note that the metal wiring layer and the contact hole are not illustrated in FIG. 3 for simplification of the drawing.

### (Effects)

The N-type diffusion layer 31a provided in the first high-side circuit region RH1 and the N-type diffusion layer 32a provided in the second high-side circuit region RH2 are isolated by the RESURF isolation structure of the first isolation region including the N-type diffusion layer 30a in the horizontal direction, and are isolated into the ground potential GND and a high voltage of 100 V or more in the vertical direction by a reverse bias of a PN junction between the P-type substrate region of the P-type substrate 10 and the N-type diffusion layers 31a and 32a.

The first and second high-side circuit regions RH1 and RH2 are both isolated into the ground potential GND and a high voltage, and the N-type diffusion layer 31a of the first high-side circuit region RH1 and the N-type diffusion layer 32a of the second high-side circuit region RH2 are electrically isolated by the isolation trench 70 having the buried insulating film 78 serving as a dielectric inside.

The high-side power supply voltage VB1 applied to the N-type diffusion layer 31a corresponds to the first power supply voltage for the first high-side circuit CH1 provided in the first high-side circuit region RH1, and the high-side power supply voltage VB2 applied to the N-type diffusion layer 32a corresponds to the second power supply voltage for the second high-side circuit CH2 provided in the second high-side circuit region RH2.

As described above, in the semiconductor device 101 as the first aspect of the first preferred embodiment, the N-type diffusion layer 31a and the N-type diffusion layer 32a are electrically isolated by the isolation trench 70, and thus, the first and second high-side circuits CH1 and CH2 can be operated by the high-side power supply voltages VB1 and VB2, respectively, with the high-side reference potential VS as the common second reference potential.

The semiconductor device 101 as the first aspect of the first preferred embodiment includes the isolation trench 70 as the isolation region 7 that electrically isolates the first and second high-side circuit regions RH1 and RH2 from each other. Therefore, in the semiconductor device 101, no trouble occurs even if the first high-side circuit CH1 provided in the first high-side circuit region RH1 is operated at the high-side power supply voltage VB1, which is the first power supply voltage, and the second high-side circuit CH2 provided in the second high-side circuit region RH2 is operated at the high-side power supply voltage VB2 which is the second power supply voltage.

Therefore, in the semiconductor device 101 as the first aspect of the first preferred embodiment, the first and second high-side circuits CH1 and CH2 respectively operating at the high-side power supply voltages VB1 and VB2, different from each other, can be provided in the high-side circuit region RH that receives the high-side reference potential VS as the common second reference potential with a structure maintaining miniaturization.

Both the N-type diffusion layers 31a and 32a, which are the first and second circuit diffusion regions, respectively, in the semiconductor device 101, satisfy the diffusion region depth requirement, which is a requirement that the formation depths thereof are deeper than that of the N-type diffusion layer 30a which is the first isolation diffusion region. Therefore, in the semiconductor device 101, a breakdown voltage in the horizontal direction can be improved by the N-type diffusion layer 30a forming the first isolation region, and a breakdown voltage in the vertical direction can be improved by the N-type diffusion layers 31a and 32a.

The semiconductor device 101 can suppress a parasitic operation between the first and second high-side circuits CH1 and CH2 by the isolation trench 70 having the buried insulating film 78 inside.

### (Second Aspect)

FIG. 4 is a cross-sectional view schematically illustrating a cross-sectional structure of the semiconductor device 102 as a second aspect of the first preferred embodiment. FIG. 4 illustrates a cross-sectional structure corresponding to the A-A cross section of FIG. 1. Note that a planar configuration and a circuit configuration of the semiconductor device 102 are similar to the configurations illustrated in FIGS. 1 and 2.

Hereinafter, points common to those of the semiconductor device 101 of the first aspect illustrated in FIG. 3 will be denoted by the same reference signs, description thereof will be omitted as appropriate, and characteristic points of the semiconductor device 102 of the second aspect will be mainly described.

In the semiconductor device 102, N⁺ buried diffusion layers 20 and 21 of the N type in contact with a substrate region of the P-type substrate 10 are provided as lower layer structures of the first and second high-side circuit regions RH1 and RH2, respectively. That is, the N⁺ buried diffusion layers 20 and 21, which are first and second buried diffusion layers, are selectively provided on the P-type substrate region in the P-type substrate 10.

Hereinafter, a case where a provisional N-type epitaxial layer is formed as an intermediate stage will be described as a first manufacturing method, and a case where a provisional P-type epitaxial layer is formed as an intermediate stage will be described as a second manufacturing method.

When the first manufacturing method is adopted, in the cross-sectional structure illustrated in FIG. 4, the N⁺ buried diffusion layers 20 and 21 are formed at the same time in an upper layer portion of the P-type substrate 10, and thereafter, the provisional N-type epitaxial layer is formed on the P-type substrate 10 including the N⁺ buried diffusion layers 20 and 21. Thereafter, the P-type diffusion layer 40 is selectively formed in the provisional N-type epitaxial layer outside the high-side circuit region RH. The provisional N-type epitaxial layer remaining after the formation of the P-type diffusion layer 40 outside the high-side circuit region RH serves as the N-type epitaxial layer 30b. The P-type diffusion layer 40 is provided so as to surround the high-side circuit region RH in plan view.

The N-type epitaxial layer 30b functions as one of first isolation diffusion regions, and the P-type diffusion layer 40 and the N-type epitaxial layer 30b constitute a first isolation region. The low-side circuit region RL and the high-side circuit region RH are electrically isolated by the P-type diffusion layer 40 and the N-type epitaxial layer 30b. At this time, the N-type epitaxial layer 30b satisfies a RESURF condition.

Further, a P-type diffusion layer 41b and the N-type diffusion layer 31b are

selectively formed in the provisional N-type epitaxial layer in the first high-side circuit region RH1, and a P-type diffusion layer 42b and the N-type diffusion layer 32b are formed in the provisional N-type epitaxial layer in the second high-side circuit region RH2. At this time, the P-type diffusion layers 41b and 42b are formed so as to reach the N⁺ buried diffusion layers 20 and 21, respectively.

In the provisional N-type epitaxial layer, a remaining region after the formation of the P-type diffusion layer 40, the P-type diffusion layers 41b and 42b, and the N-type diffusion layers 31b and 32b serves as the N-type epitaxial layer 30b.

On the other hand, when the second manufacturing method is adopted, the N⁺ buried diffusion layers 20 and 21 are formed at the same time in the upper layer portion of the P-type substrate 10, and thereafter, a provisional P-type epitaxial layer is formed on the P-type substrate 10 including the N⁺ buried diffusion layers 20 and 21. Thereafter, an N-type diffusion layer 30b2 (not illustrated) is selectively formed in the provisional P-type epitaxial layer. The N-type diffusion layer 30b2 corresponds to the N-type epitaxial layer 30b illustrated in FIG. 4, and forms a RESURF region.

Further, the P-type diffusion layer 40 is selectively formed in the provisional P-type epitaxial layer. A P-type impurity concentration of the P-type diffusion layer 40 is set to be higher than a P-type impurity concentration of the provisional P-type epitaxial layer. Therefore, a region surrounded by the P-type diffusion layer 40 in plan view serves as the N-type diffusion layer 30b2.

In addition, the P-type diffusion layer 41b and the N-type diffusion layer 31b are selectively formed in the provisional P-type epitaxial layer in the first high-side circuit region RH1, and the P-type diffusion layer 42b and the N-type diffusion layer 32b are formed in the provisional P-type epitaxial layer in the second high-side circuit region RH2. At this time, the N-type diffusion layers 31b and 32b are formed so as to reach the N⁺ buried diffusion layers 20 and 21, respectively.

When the first manufacturing method is adopted, the N⁺ buried diffusion layers 20 and 21 are in contact with a lower surface of the provisional N-type epitaxial layer in the intermediate stage. Similarly, when the second manufacturing method is adopted, the N⁺ buried diffusion layers 20 and 21 are in contact with a lower surface of the provisional

P-type epitaxial layer in the intermediate stage.

As described above, the N-type diffusion layers 31b and 32b and the P-type diffusion layers 41b and 42b are provided in the provisional N-type epitaxial layer or the provisional P-type epitaxial layer.

In the case of the first manufacturing method, a part of the provisional N-type epitaxial layer may be used as the N-type diffusion layers 31b and 32b. In this case, the provisional N-type epitaxial layer remaining after the formation of the P-type diffusion layer 41b in the first high-side circuit region RH1 serves as the N-type diffusion layer 31b, and the provisional N-type epitaxial layer remaining after the formation of the P-type diffusion layer 42b in the second high-side circuit region RH2 serves as the N-type diffusion layer 32b.

In the case of the second manufacturing method, a part of the provisional P-type epitaxial layer may be the P-type diffusion layers 41b and 42b. In this case, the provisional P-type epitaxial layer remaining after the formation of the N-type diffusion layer 31b in the first high-side circuit region RH1 serves as the P-type diffusion layer 41b, and the provisional P-type epitaxial layer remaining after the formation of the N-type diffusion layer 32b in the second high-side circuit region RH2 serves as the P-type diffusion layer 42b.

In the semiconductor device 102, the isolation region 7 is provided with an isolation trench 71 that penetrates the N-type diffusion layers 31b and 32b and the N⁺ buried diffusion layers 20 and 21 and reaches the P-type substrate region in the P-type substrate 10.

The N-type diffusion layer 31b and the N-type diffusion layer 32b are electrically isolated by the isolation trench 71. The isolation trench 71 is formed as follows, for example.

When the first manufacturing method is adopted, the isolation trench 71 is formed in the isolation region 7 so as to reach the substrate region from a surface of the P-type substrate 10 including the provisional N-type epitaxial layer and the N⁺ buried diffusion layers 20 and 21. The N⁺ buried diffusion layers 20 and 21 formed at the same time are electrically isolated by the isolation trench 71 formed in this manner.

When the second manufacturing method is adopted, the isolation trench 71 is formed in the isolation region 7 so as to reach the substrate region from a surface of the P-type substrate 10 including the provisional P-type epitaxial layer and the N⁺ buried diffusion layers 20 and 21. The N⁺ buried diffusion layers 20 and 21 formed at the same time are electrically isolated by the isolation trench 71 formed in this manner.

In addition, the N-type diffusion layers 31b and 32b may also be isolated by the isolation trench 71 similarly to the N-type diffusion layers 31a and 32a formed in the semiconductor device 101.

As described above, the semiconductor device 102 includes the N⁺ buried diffusion layer 20 provided on the substrate region of the P-type substrate 10 and the N-type diffusion layer 31b selectively provided on the N⁺ buried diffusion layer 20 as first circuit diffusion regions. The N⁺ buried diffusion layer 20 serves as a first buried diffusion layer, and the N-type diffusion layer 31b serves as a first surface diffusion layer.

The semiconductor device 102 further includes, as second circuit diffusion regions, the N⁺ buried diffusion layer 21 provided on the substrate region of the P-type substrate 10 and the N-type diffusion layer 32b selectively provided on the N⁺ buried diffusion layer 21. The N⁺ buried diffusion layer 21 serves as a second buried diffusion layer, and the N-type diffusion layer 32b serves as a second surface diffusion layer.

Note that the N⁺ diffusion layer 53 and the P⁺ diffusion layers 62 and 63 are selectively provided in a surface of the N-type diffusion layer 31b similarly to the N-type diffusion layer 31a. In addition, the N⁺ diffusion layer 54 and the P⁺ diffusion layers 64 and 65 are selectively provided in a surface of the N-type diffusion layer 32b similarly to the N-type diffusion layer 32a.

Note that the P⁺ diffusion layer 61 and the N⁺ diffusion layers 51 and 52 are selectively provided in a surface of the P-type diffusion layer 41b similarly to the P-type diffusion layer 41a. In addition, the P⁺ diffusion layer 66 and the N⁺ diffusion layers 55 and 56 are selectively provided in a surface of the P-type diffusion layer 42b similarly to the P-type diffusion layer 42a.

In the semiconductor device 102, the isolation trench 71 is provided in the isolation region 7. The isolation trench 71 is provided between the N-type diffusion layer 31b and the N⁺ buried diffusion layer 20 serving as the first circuit diffusion regions and the N-type diffusion layer 32b and the N⁺ buried diffusion layer 21 serving as the second circuit diffusion regions, and is provided such that the deepest portion reaches the P-type substrate region in the P-type substrate 10.

The N-type diffusion layer 31b and the N⁺ buried diffusion layer 20 are electrically isolated from the N-type diffusion layer 32b and the N⁺ buried diffusion layer 21 by the isolation trench 71.

Similarly to the isolation trench 70, the isolation trench 71 includes the buried insulating film 78, configured to insulate and isolate the first and second high-side circuit regions RH1 and RH2 from each other, inside.

The semiconductor device 102 as the second aspect of the first preferred embodiment includes the isolation trench 71 as the isolation region 7 that electrically isolates the first and second high-side circuit regions RH1 and RH2 from each other.

Therefore, in the semiconductor device 102 as the second aspect of the first preferred embodiment, the first and second high-side circuits CH1 and CH2 operating at the high-side power supply voltages VB1 and VB2, respectively, can be provided in the high-side circuit region RH with a structure maintaining miniaturization as in the semiconductor device 101.

In the semiconductor device 102, both the N⁺ buried diffusion layer 20, which is the first buried diffusion layer constituting a part of the first circuit diffusion region, and the N⁺ buried diffusion layer 21, which is the second buried diffusion layer constituting a part of the second circuit diffusion region, have a formation depth deeper than that of the N-type diffusion layer 30a which is the first isolation diffusion region.

The N⁺ buried diffusion layer 20 and the N-type diffusion layer 31b constitute the first circuit diffusion region, and the N⁺ buried diffusion layer 21 and the N-type diffusion layer 32b constitute the second circuit diffusion region. Therefore, the semiconductor device 102 also satisfies a diffusion region depth requirement that “a formation depth of each of the first and second circuit diffusion regions is deeper than a formation depth of the first isolation diffusion region” similarly to the semiconductor device 101.

Therefore, in the semiconductor device 102, a breakdown voltage in the horizontal direction can be improved by the N-type diffusion layer 30a constituting the first isolation region, and a breakdown voltage in the vertical direction can be improved by a combination of the N-type diffusion layer 31b and the N⁺ buried diffusion layer 20 and a combination of the N-type diffusion layer 32b and the N⁺ buried diffusion layer 21.

The semiconductor device 102 can suppress a parasitic operation between the first and second high-side circuits CH1 and CH2 by the isolation trench 71 having the buried insulating film 78 inside similarly to the semiconductor device 101.

In addition, in the semiconductor device 102, a first combination structure of the N⁺ buried diffusion layer 20 and the N-type diffusion layer 31b can relatively easily satisfy the diffusion region depth requirement, and a second combination structure of the N⁺ buried diffusion layer 21 and the N-type diffusion layer 32b can relatively easily satisfy the diffusion region depth requirement.

### (Third Aspect)

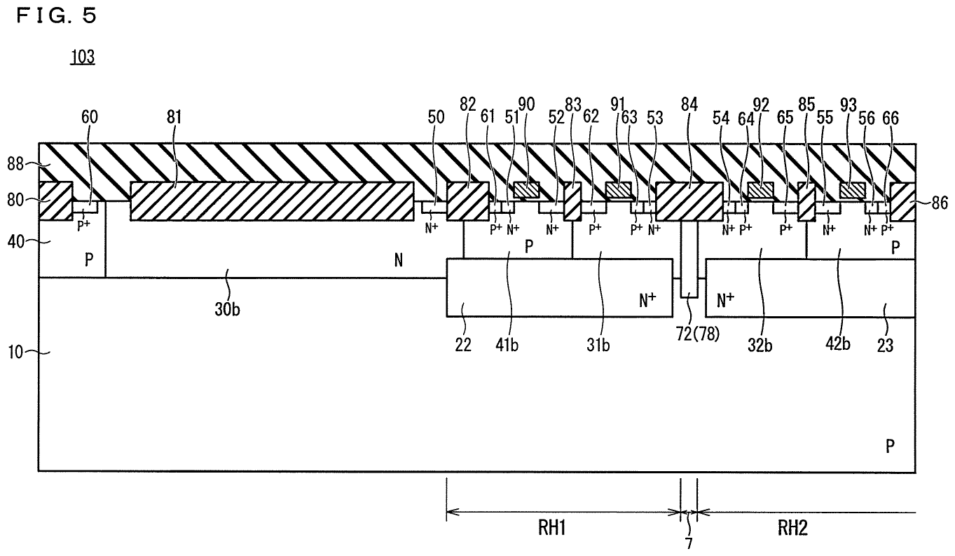

FIG. 5 is a cross-sectional view schematically illustrating a cross-sectional structure of a semiconductor device 103 as a third aspect of the first preferred embodiment. FIG. 5 illustrates a cross-sectional structure corresponding to the A-A cross section of FIG. 1. Note that a planar configuration and a circuit configuration of the semiconductor device 103 are similar to the configurations illustrated in FIGS. 1 and 2.

Hereinafter, points common to those of the semiconductor device 102 of the second aspect illustrated in FIG. 4 will be denoted by the same reference signs, description thereof will be omitted as appropriate, and characteristic points of the semiconductor device 103 of the third aspect will be mainly described.

The semiconductor device 103 of the third aspect has a structure in which the N⁺ buried diffusion layers 20 and 21 of the semiconductor device 102 are replaced with N⁺ buried diffusion layers 22 and 23, and the isolation trench 71 is replaced with an isolation trench 72.

Therefore, the N⁺ buried diffusion layer 22 serves as a first buried diffusion layer, and the N⁺ buried diffusion layer 23 serves as a second buried diffusion layer. That is, the N⁺ buried diffusion layers 22 and 23 are selectively provided on a substrate region of the P-type substrate 10.

As in the second aspect, the N-type diffusion layer 31b serves as a first surface diffusion layer, and the N-type diffusion layer 32b serves as a second surface diffusion layer. That is, the N-type diffusion layer 31b is selectively provided on the N⁺ buried diffusion layer 22, and the N-type diffusion layer 32b is selectively provided on the N⁺ buried diffusion layer 23.

In the semiconductor device 102 of the second aspect illustrated in FIG. 4, the N⁺ buried diffusion layers 20 and 21 are isolated by the isolation trench 71, and each of the N⁺ buried diffusion layers 20 and 21 is in contact with a sidewall of the isolation trench 71.

On the other hand, in the semiconductor device 103 of the third aspect, the N⁺ buried diffusion layers 22 and 23 are isolated by a pattern to be formed discretely at the time of forming the N⁺ buried diffusion layers 22 and 23 as illustrated in FIG. 5. Therefore, a P-type substrate region exists between the N⁺ buried diffusion layers 22 and 23.

Note that the N⁺ buried diffusion layers 22 and 23 are formed by a manufacturing method similar to that of the N⁺ buried diffusion layers 22 and 23 except that the N⁺ buried diffusion layers 20 and 21 are discretely formed.

In the semiconductor device 103, the isolation region 7 is provided with the isolation trench 72 that penetrates the N-type diffusion layers 31b and 32b and reaches the substrate region of the P-type substrate 10 between the N⁺ buried diffusion layers 22 and 23.

As illustrated in FIG. 5, the N⁺ buried diffusion layers 22 and 23 have a certain interval wider than a formation width of the isolation trench 72, and thus, a sidewall portion of the isolation trench 72 is not in contact with any of the N⁺ buried diffusion layers 22 and 23.

The isolation trench 72 reaches the P-type substrate region in the P-type substrate 10, but the deepest portion of the isolation trench 72 is provided to be shallower than the deepest portion of each of the N⁺ buried diffusion layers 22 and 23.

That is, the isolation trench 72 does not have a contact relationship with each of the N⁺ buried diffusion layers 22 and 23. Then, the isolation trench 72 of the semiconductor device 103 satisfies a trench depth requirement which is a requirement that “a formation depth of the isolation trench 72 is shallower than a formation depth of each of the N⁺ buried diffusion layers 22 and 23 which are the first and second buried diffusion layers”.

Similarly to the isolation trenches 70 and 71, the isolation trench 72 includes the buried insulating film 78, configured to insulate and isolate the first and second high-side circuit regions RH1 and RH2 from each other, inside.

The semiconductor device 103 as the third aspect of the first preferred embodiment includes the isolation trench 72 as the isolation region 7 that electrically isolates the first and second high-side circuit regions RH1 and RH2 from each other.

Therefore, in the semiconductor device 103 as the third aspect of the first preferred embodiment, the first and second high-side circuits CH1 and CH2 operating at the high-side power supply voltages VB1 and VB2, respectively, can be provided in the high-side circuit region RH with a structure maintaining miniaturization as in the semiconductor devices 101 and 102.

In the semiconductor device 103, both the N⁺ buried diffusion layer 22, which is the first buried diffusion layer constituting a part of a first circuit diffusion region, and the N⁺ buried diffusion layer 23, which is the second buried diffusion layer constituting a part of a second circuit diffusion region, have a formation depth deeper than that of the N-type epitaxial layer 30b which is a first isolation diffusion region.

The N⁺ buried diffusion layer 22 and the N-type diffusion layer 31b constitute the first circuit diffusion region, and the N⁺ buried diffusion layer 23 and the N-type diffusion layer 32b constitute the second circuit diffusion region. Therefore, the semiconductor device 103 also satisfies a diffusion region depth requirement that “a formation depth of each of the first and second circuit diffusion regions is deeper than a formation depth of the first isolation diffusion region” similarly to the semiconductor devices 101 and 102.

Therefore, in the semiconductor device 103, a breakdown voltage in the horizontal direction can be improved by the N-type epitaxial layer 30b constituting a first isolation region, and a breakdown voltage in the vertical direction can be improved by a first combination of the N-type diffusion layer 31b and the N⁺ buried diffusion layer 22 and a second combination of the N-type diffusion layer 32b and the N⁺ buried diffusion layer 23.

The semiconductor device 103 can suppress a parasitic operation between the first and second high-side circuits CH1 and CH2 by the isolation trench 72 having the buried insulating film 78 inside similarly to the semiconductor devices 101 and 102.

In addition, in the semiconductor device 103, a first combination structure of the N⁺ buried diffusion layer 22 and the N-type diffusion layer 31b can relatively easily satisfy the diffusion region depth requirement, and a second combination structure of the N⁺ buried diffusion layer 23 and the N-type diffusion layer 32b can relatively easily satisfy the diffusion region depth requirement.

Further, since the isolation trench 72 of the semiconductor device 103 as the third aspect of the first preferred embodiment satisfies the trench depth requirement, a process load at the time of forming the isolation trench 72 can be reduced as much as the formation depth of the isolation trench 72 can be made relatively shallow.

In addition, in the semiconductor device 103, the sidewall portion of the isolation trench 72 is not in contact with any of the N⁺ buried diffusion layers 22 and 23, and a discrete distance between the N⁺ buried diffusion layers 22 and 23 is set to be relatively long. Therefore, the semiconductor device 103 can further increase the degree of electrical isolation between the N⁺ buried diffusion layers 22 and 23.

### Second Preferred Embodiment

### (First Aspect)

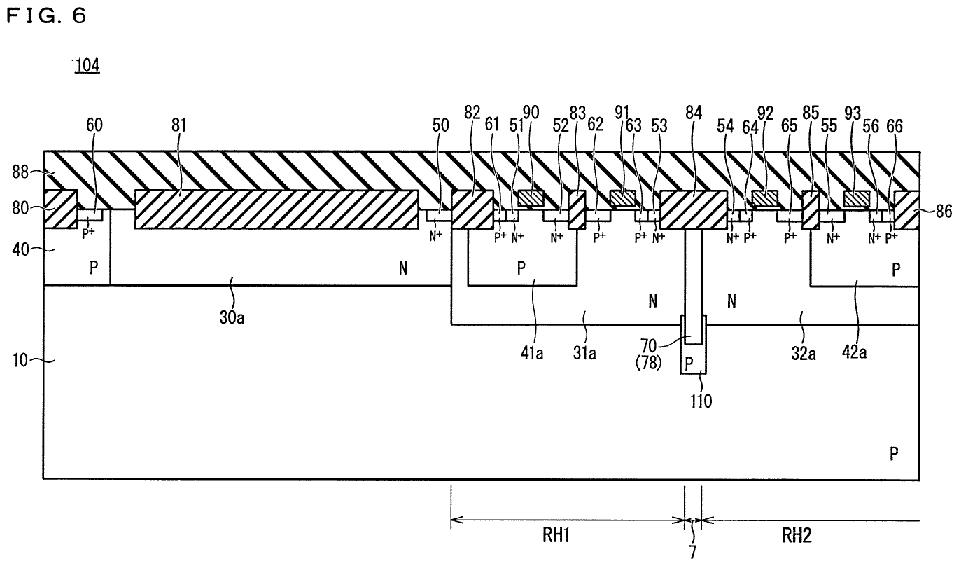

FIG. 6 is a cross-sectional view schematically illustrating a cross-sectional structure of a semiconductor device 104 as a first aspect of the second preferred embodiment. FIG. 6 illustrates a cross-sectional structure corresponding to the A-A cross section of FIG. 1. Note that a planar configuration and a circuit configuration of the semiconductor device 104 are similar to the configurations illustrated in FIGS. 1 and 2.

Hereinafter, points common to those of the semiconductor device 101 of the first aspect of the first preferred embodiment illustrated in FIG. 3 will be denoted by the same reference signs, description thereof will be omitted as appropriate, and characteristic points of the semiconductor device 104 of the first aspect of the second preferred embodiment will be mainly described.

In addition to the structure of the semiconductor device 101, the semiconductor device 104 further includes a P-type diffusion layer 110 provided in contact with the deepest portion of the isolation trench 70 in the periphery of the deepest portion of the isolation trench 70 in a substrate region of the P-type substrate 10. The P-type diffusion layer 110 serves as a trench bottom diffusion region. In the structure illustrated in FIG. 6, an upper surface of the P-type diffusion layer 110 is present at a position higher than lower surfaces of the N-type diffusion layers 31a and 32a, and the P-type diffusion layer 110 also has a contact relationship with the N-type diffusion layers 31a and 32a.

A P-type impurity concentration in the P-type diffusion layer 110 is set to be higher than a P-type impurity concentration in the substrate region of the P-type substrate 10.

After an empty trench for the isolation trench 70 is formed by trench etching in a step of forming the isolation trench 70, a step of manufacturing the P-type diffusion layer 110 is executed before the buried insulating film 78 is formed in the isolation trench 70. The P-type diffusion layer 110 is formed by ion implantation, diffusion processing, or the like of P-type impurities from above the P-type substrate 10 through the empty isolation trench 70.

The semiconductor device 104 as the first aspect of the second preferred embodiment has effects similar to those of the semiconductor device 101 as the first aspect of the first preferred embodiment, and further has the following unique effect.

Since the semiconductor device 104 as the first aspect of the second preferred embodiment includes the P-type diffusion layer 110 which is the trench bottom diffusion region, it is possible to suppress a leakage current due to a parasitic bipolar transistor passing through a P-type substrate region in the P-type substrate 10.

The parasitic bipolar transistor in the semiconductor device 101 as the first aspect of the first preferred embodiment is a parasitic NPN bipolar transistor formed by the N-type diffusion layer 31a, the P-type substrate region in the P-type substrate 10, and the N-type diffusion layer 32a. That is, an operation of the above-described parasitic NPN bipolar transistor can be considered as a parasitic operation assumed in the semiconductor device 101. Meanwhile, in the semiconductor device 104 as the first aspect of the second preferred embodiment, the P-type diffusion layer 110 is provided in a base region of the parasitic NPN bipolar transistor.

As described above, since the P-type diffusion layer 110 having a relatively high P-type impurity concentration is provided at the bottom of the isolation trench 70 in the semiconductor device 104, a current amplification factor hFE of the NPN bipolar transistor passing through the P-type substrate region in the P-type substrate 10 can be reduced, and the leakage current between the first and second high-side circuit regions RH1 and RH2 generated by the operation of the parasitic NPN bipolar transistor can be suppressed.

### (Second Aspect)

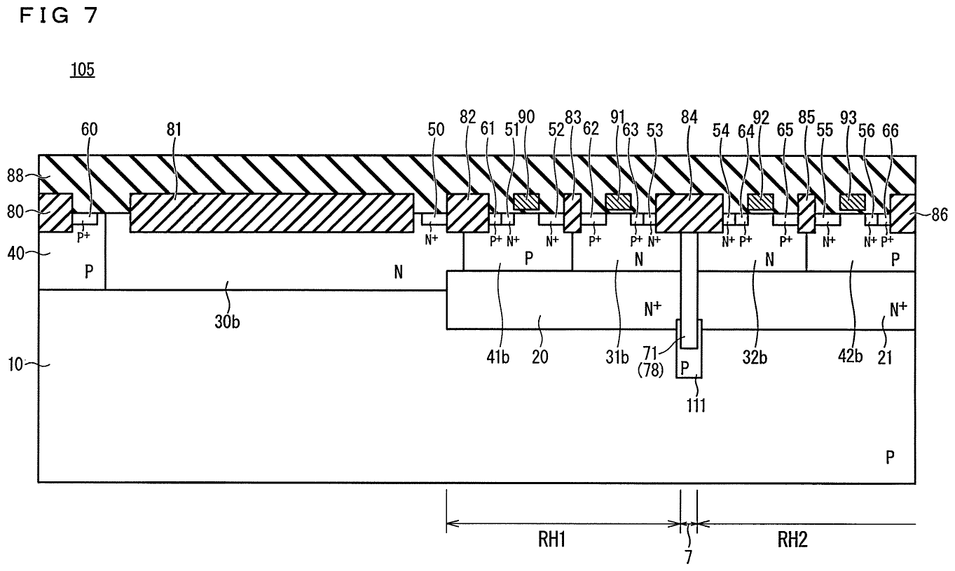

FIG. 7 is a cross-sectional view schematically illustrating a cross-sectional structure of a semiconductor device 105 as a second aspect of the second preferred embodiment. FIG. 7 illustrates a cross-sectional structure corresponding to the A-A cross section of FIG. 1. Note that a planar configuration and a circuit configuration of the semiconductor device 105 are similar to the configurations illustrated in FIGS. 1 and 2.

Hereinafter, points common to those of the semiconductor device 102 of the second aspect of the first preferred embodiment illustrated in FIG. 4 will be denoted by the same reference signs, description thereof will be omitted as appropriate, and characteristic points of the semiconductor device 105 of the second aspect of the second preferred embodiment will be mainly described.

In addition to the structure of the semiconductor device 102, the semiconductor device 105 further includes a P-type diffusion layer 111 provided in contact with the deepest portion of the isolation trench 71 in the periphery of the deepest portion of the isolation trench 71 in a substrate region of the P-type substrate 10. The P-type diffusion layer 111 serves as a trench bottom diffusion region. In the structure illustrated in FIG. 7, an upper surface of the P-type diffusion layer 111 is present at a position higher than lower surfaces of the N⁺ buried diffusion layers 20 and 21, and the P-type diffusion layer 111 also has a contact relationship with the N⁺ buried diffusion layers 20 and 21.

A P-type impurity concentration in the P-type diffusion layer 111 is set to be higher than a P-type impurity concentration in the substrate region of the P-type substrate 10.

After an empty trench for the isolation trench 71 is formed by trench etching in a step of forming the isolation trench 71, a step of manufacturing the P-type diffusion layer 111 is executed before the buried insulating film 78 is formed in the isolation trench 71. The P-type diffusion layer 111 is formed by ion implantation, diffusion processing, or the like of P-type impurities from above the P-type substrate 10 through the empty isolation trench 71.

As another step of manufacturing the P-type diffusion layer 111, in a case where the first manufacturing method is adopted at the time of manufacturing the semiconductor device 102, it is conceivable to selectively form the P-type diffusion layer 111 as a buried diffusion layer in an upper layer portion of the P-type substrate 10 before formation of a provisional N-type epitaxial layer.

The semiconductor device 105 as the second aspect of the second preferred embodiment has effects similar to those of the semiconductor device 102 as the second aspect of the first preferred embodiment, and further has the following unique effect.

Since the semiconductor device 105 as the second aspect of the second preferred embodiment includes the P-type diffusion layer 111 which is the trench bottom diffusion region, it is possible to suppress a leakage current due to a parasitic bipolar transistor passing through a P-type substrate region in the P-type substrate 10 as in the first aspect of the second preferred embodiment.

The parasitic bipolar transistor in the semiconductor device 102 as the second aspect of the first preferred embodiment is a parasitic NPN bipolar transistor formed by the N⁺ buried diffusion layer 20, the P-type substrate region of the P-type substrate 10, and the N⁺ buried diffusion layer 21. That is, an operation of the above-described parasitic NPN bipolar transistor can be considered as a parasitic operation assumed in the semiconductor device 102. Meanwhile, in the semiconductor device 105 as the second aspect of the second preferred embodiment, the P-type diffusion layer 111 is provided in a base region of the parasitic NPN bipolar transistor.

### (Third Aspect)

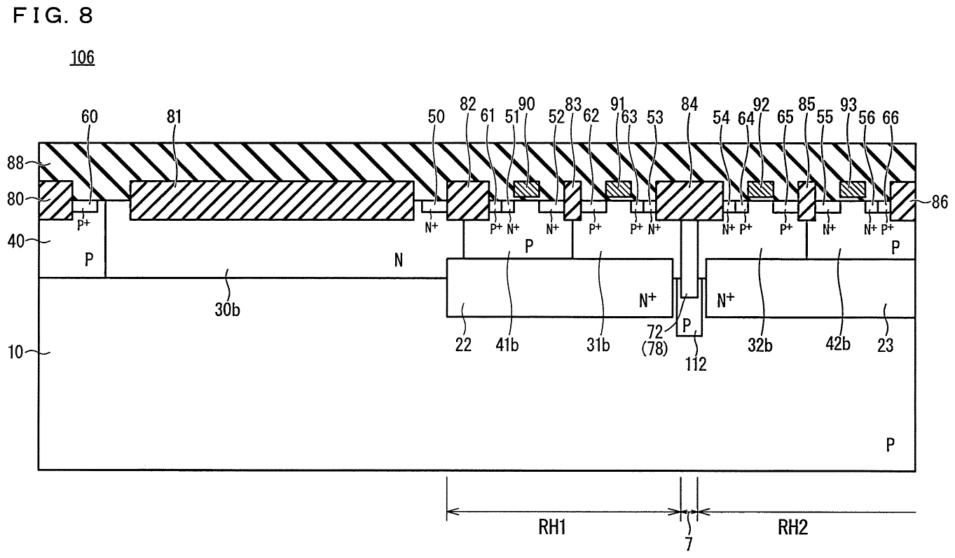

FIG. 8 is a cross-sectional view schematically illustrating a cross-sectional structure of a semiconductor device 106 as a third aspect of the second preferred embodiment. FIG. 8 illustrates a cross-sectional structure corresponding to the A-A cross section of FIG. 1. Note that a planar configuration and a circuit configuration of the semiconductor device 106 are similar to the configurations illustrated in FIGS. 1 and 2.

Hereinafter, points common to those of the semiconductor device 103 of the third aspect of the first preferred embodiment illustrated in FIG. 5 will be denoted by the same reference signs, description thereof will be omitted as appropriate, and characteristic points of the semiconductor device 106 of the third aspect of the second preferred embodiment will be mainly described.

In addition to the structure of the semiconductor device 103, the semiconductor device 106 further includes a P-type diffusion layer 112 provided in contact with the deepest portion of the isolation trench 72 in the periphery of the deepest portion of the isolation trench 72 in a substrate region of the P-type substrate 10. The P-type diffusion layer 112 serves as a trench bottom diffusion region.

In the structure illustrated in FIG. 8, the P-type diffusion layer 112 also has a contact relationship with the N-type diffusion layers 31b and 32b. Further, the P-type diffusion layer 112 is provided in a substrate region of the P-type substrate 10 between the N⁺ buried diffusion layers 22 and 23.

A P-type impurity concentration in the P-type diffusion layer 112 is set to be higher than a P-type impurity concentration in the substrate region of the P-type substrate 10.

After an empty trench for the isolation trench 72 is formed by trench etching in a step of forming the isolation trench 72, a step of manufacturing the P-type diffusion layer 112 is executed before the buried insulating film 78 is formed in the isolation trench 72. The P-type diffusion layer 112 is formed by ion implantation, diffusion processing, or the like of P-type impurities from above the P-type substrate 10 through the empty isolation trench 72.

As another step of manufacturing the P-type diffusion layer 112, in a case where a first manufacturing method of forming a provisional N-type epitaxial layer in an intermediate stage is adopted at the time of manufacturing the semiconductor device 103, it is conceivable to selectively form the P-type diffusion layer 112 as a buried diffusion layer in an upper layer portion of the P-type substrate 10 before formation of a provisional N-type epitaxial layer.

The semiconductor device 106 as the third aspect of the second preferred embodiment has effects similar to those of the semiconductor device 103 as the third aspect of the first preferred embodiment, and further has the following unique effect.

Since the semiconductor device 106 as the third aspect of the second preferred embodiment includes the P-type diffusion layer 112 which is the trench bottom diffusion region, it is possible to suppress a leakage current due to a parasitic bipolar transistor passing through a P-type substrate region in the P-type substrate 10 as in the first and second aspects of the second preferred embodiment.

The parasitic bipolar transistor in the semiconductor device 103 as the third aspect of the first preferred embodiment is a parasitic NPN bipolar transistor formed by the N⁺ buried diffusion layer 22, the P-type substrate region in the P-type substrate 10, and the N⁺ buried diffusion layer 23. That is, an operation of the above-described parasitic NPN bipolar transistor can be considered as a parasitic operation assumed in the semiconductor device 103. Meanwhile, in the semiconductor device 106 as the third aspect of the second preferred embodiment, the P-type diffusion layer 112 is provided in a base region of the parasitic NPN bipolar transistor.

### Third Preferred Embodiment

### (First Aspect)

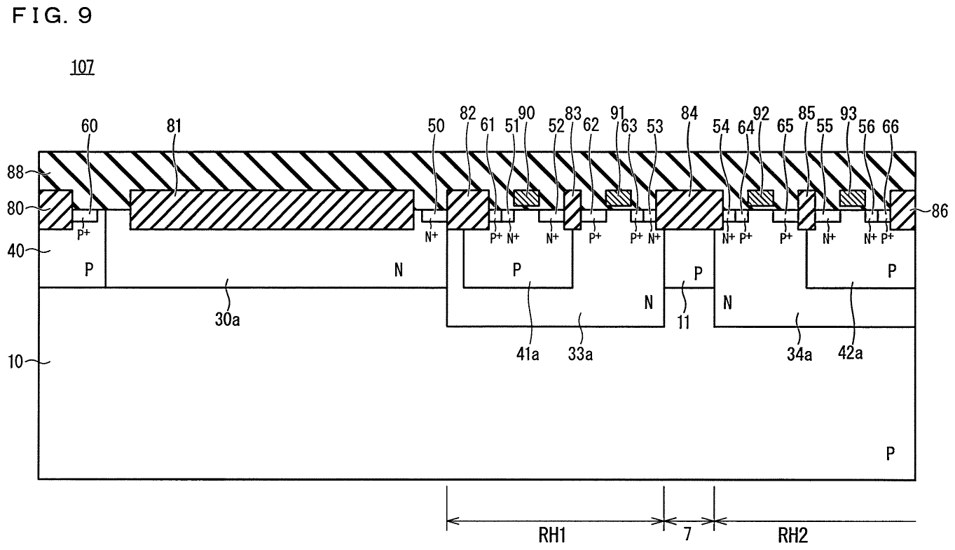

FIG. 9 is a cross-sectional view schematically illustrating a cross-sectional structure of a semiconductor device 107 as a first aspect of the third preferred embodiment. FIG. 9 illustrates a cross-sectional structure corresponding to the A-A cross section of FIG. 1. Note that a planar configuration and a circuit configuration of the semiconductor device 107 are similar to the configurations illustrated in FIGS. 1 and 2.

Hereinafter, points common to those of the semiconductor device 101 of the first aspect of the first preferred embodiment illustrated in FIG. 3 will be denoted by the same reference signs, description thereof will be omitted as appropriate, and characteristic points of the semiconductor device 107 of the first aspect of the third preferred embodiment will be mainly described.

In the semiconductor device 107, a P-type layer 11 is provided in place of the isolation trench 70 of the semiconductor device 101, an N-type diffusion layer 33a is provided in place of the N-type diffusion layer 31a, and an N-type diffusion layer 34a is provided in place of the N-type diffusion layer 32a.

The semiconductor device 107 as the first aspect of the third preferred embodiment includes the P-type layer 11, which serves as a second isolation diffusion region, as the isolation region 7. The P-type layer 11 is provided between the N-type diffusion layer 33a serving as a first circuit diffusion region and the N-type diffusion layer 34a serving as a second circuit diffusion region so as to be in contact with each of the N-type diffusion layers 33a and 34a.

Hereinafter, first and second manufacturing methods of the P-type layer 11 will be described. The first manufacturing method is a method of selectively forming the N-type diffusion layers 33a and 34a in an upper layer portion of the P-type substrate 10. A remaining region in a surface of the P-type substrate 10 where the N-type diffusion layers 33a and 34a are not formed serves as the P-type layer 11.

The second manufacturing method is a method of forming the P-type layer 11 having a higher P-type impurity concentration than a substrate region of the P-type substrate 10 in the upper layer portion of the P-type substrate 10 by ion implantation, diffusion treatment, or the like.

When the second manufacturing method is adopted, the N-type diffusion layers 33a and 34a can be manufactured using a manufacturing method similar to that of the N-type diffusion layers 31a and 32a.

Note that the N⁺ diffusion layer 53 and the P⁺ diffusion layers 62 and 63 are selectively provided in a surface of the N-type diffusion layer 33a similarly to the N-type diffusion layers 31a and 31b. In addition, the N⁺ diffusion layer 54 and the P⁺ diffusion layers 64 and 65 are selectively provided in a surface of the N-type diffusion layer 34a similarly to the N-type diffusion layers 32a and 32b. In addition, a thermal oxide film 84 provided on the P-type layer 11 is formed simultaneously with the thermal oxide film 81 after formation of the N-type diffusion layer 30a.

The semiconductor device 107 as the first aspect of the third preferred embodiment has effects similar to those of the semiconductor device 101 as the first aspect of the first preferred embodiment, and further has the following unique effect.

The semiconductor device 107 includes the P-type layer 11 which is the second isolation diffusion region provided in contact with each of the N-type diffusion layers 33a and 34a between the N-type diffusion layer 33a serving as the first circuit diffusion region and the N-type diffusion layer 34a serving as the second circuit diffusion region.

Since the semiconductor device 107 as the first aspect of the third preferred embodiment includes the P-type layer 11 in the isolation region 7 as the second isolation diffusion region, the first and second high-side circuit regions RH1 and RH2 can be electrically isolated from each other with a relatively simple structure.

Since the P-type layer 11 has an electrical connection relationship with the P-type substrate region of the P-type substrate 10, a potential thereof is the ground potential GND, and the N-type diffusion layers 33a and 34a respectively receiving the high-side power supply voltages VB1 and VB2 have high voltages of 100 V or more, so that a PN junction between the N-type diffusion layers 33a and 34a and the P-type substrate 10 and the P-type layer 12 is set to a reverse bias state.

Therefore, the first and second high-side circuit regions RH1 and RH2 are electrically isolated from each other by the reverse bias of the PN junction.

The P-type layer 11 can be formed without an additional step in a wafer process (WP) step or by adding relatively small number of steps such as photoengraving, ion implantation, and subsequent diffusion treatment. That is, in a step of forming the P-type layer 11, a process load can be reduced as compared with the step of forming the isolation trenches 70 to 72 described in the first or second preferred embodiment.

### (Second Aspect)

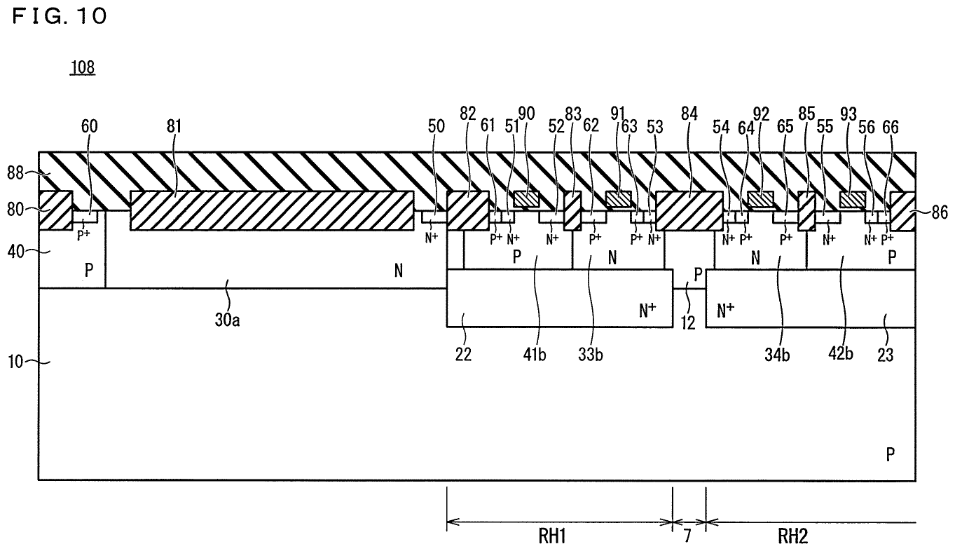

FIG. 10 is a cross-sectional view schematically illustrating a cross-sectional structure of a semiconductor device 108 as a second aspect of the third preferred embodiment. FIG. 10 illustrates a cross-sectional structure corresponding to the A-A cross section of FIG. 1. Note that a planar configuration and a circuit configuration of the semiconductor device 108 are similar to the configurations illustrated in FIGS. 1 and 2.

Hereinafter, points common to those of the semiconductor device 103 of the third aspect of the first preferred embodiment illustrated in FIG. 5 will be denoted by the same reference signs, description thereof will be omitted as appropriate, and characteristic points of the semiconductor device 108 of the second aspect of the third preferred embodiment will be mainly described.

In the semiconductor device 108, a P-type layer 12 is provided in place of the isolation trench 72 of the semiconductor device 103, an N-type diffusion layer 33b is provided in place of the N-type diffusion layer 31b, and an N-type diffusion layer 34b is provided in place of the N-type diffusion layer 32b. Therefore, the N-type diffusion layer 33b serves as a first surface diffusion layer, and the N-type diffusion layer 34b serves as a second surface diffusion layer.

The semiconductor device 108 as the second aspect of the third preferred embodiment is provided with the P-type layer 12, which serves as a second isolation diffusion region, as the isolation region 7. The P-type layer 12 is provided between a first combination structure of the N-type diffusion layer 33b and the N⁺ buried diffusion layer 22 serving as a first circuit diffusion region and a second combination structure of the N-type diffusion layer 34b and the N⁺ buried diffusion layer 23 serving as a second circuit diffusion region. The P-type layer 12 has a contact relationship with the N-type diffusion layers 33b and 34b and the N⁺ buried diffusion layers 22 and 23, and functions as the second isolation diffusion region.

Note that the N⁺ diffusion layer 53 and the P⁺ diffusion layers 62 and 63 are selectively provided in a surface of the N-type diffusion layer 33b similarly to the N-type diffusion layers 31a, 31b, and 33a. In addition, the N⁺ diffusion layer 54 and the P⁺ diffusion layers 64 and 65 are selectively provided in a surface of the N-type diffusion layer 34b similarly to the N-type diffusion layers 32a, 32b, and 34a.

Hereinafter, first and second manufacturing methods of the P-type layer 12 will be described. The first manufacturing method is a method of forming a provisional N-type epitaxial layer on the P-type substrate 10, and then, forming the P-type layer 12 by ion implantation, diffusion treatment, or the like from the inside of the provisional N-type epitaxial layer to a substrate region of the P-type substrate 10.

The second manufacturing method is a method of forming a provisional P-type epitaxial layer on the P-type substrate 10, and forming the P-type layer 12 as a remaining region after formation of the N-type diffusion layers 33b and 34b in the provisional P-type epitaxial layer. In this case, a P-type impurity concentration of the provisional P-type epitaxial layer needs to be set to a concentration that is equal to or higher than a P-type impurity concentration of the substrate region of the P-type substrate 10.

Note that the N-type diffusion layers 33b and 34b can be manufactured similarly to the N-type diffusion layers 31b and 32b of the semiconductor device 103.

The semiconductor device 108 as the second aspect of the third preferred embodiment has effects similar to those of the semiconductor device 103 as the third aspect of the first preferred embodiment, and further has the following unique effect.

The semiconductor device 108 includes the P-type layer 12 between the first combination structure of the N-type diffusion layer 33b and the N⁺ buried diffusion layer 22 serving as the first circuit diffusion region and the second combination structure of the N-type diffusion layer 34b and the N⁺ buried diffusion layer 23 serving as the second circuit diffusion region. The P-type layer 12 has a contact relationship with each of the N-type diffusion layers 33b and 34b and the N⁺ buried diffusion layers 22 and 23.

Since the semiconductor device 108 as the second aspect of the third preferred embodiment includes the P-type layer 12 in the isolation region 7 as the second isolation diffusion region, the first and second high-side circuit regions RH1 and RH2 can be electrically isolated from each other with a relatively simple structure.

Since the P-type layer 12 has an electrical connection relationship with the P-type substrate region in the P-type substrate 10, a potential thereof is the ground potential GND, and the N-type diffusion layers 33b and 34b respectively receiving the high-side power supply voltages VB1 and VB2 have high voltages of 100 V or more, so that a PN junction between the N-type diffusion layers 33b and 34b and the P-type substrate 10 and the P-type layer 12 is set to a reverse bias state.

Therefore, the first and second high-side circuit regions RH1 and RH2 are electrically isolated from each other by the reverse bias of the PN junction.

Similarly to the P-type layer 11, the P-type layer 12 can be formed without an additional step in a WP step or by adding relatively small number of steps such as photoengraving, ion implantation, and subsequent diffusion treatment. That is, in a step of forming the P-type layer 12, a process load can be reduced as compared with the step of forming the isolation trenches 70 to 72 described in the first or second preferred embodiment.

### Fourth Preferred Embodiment

### (First Aspect)

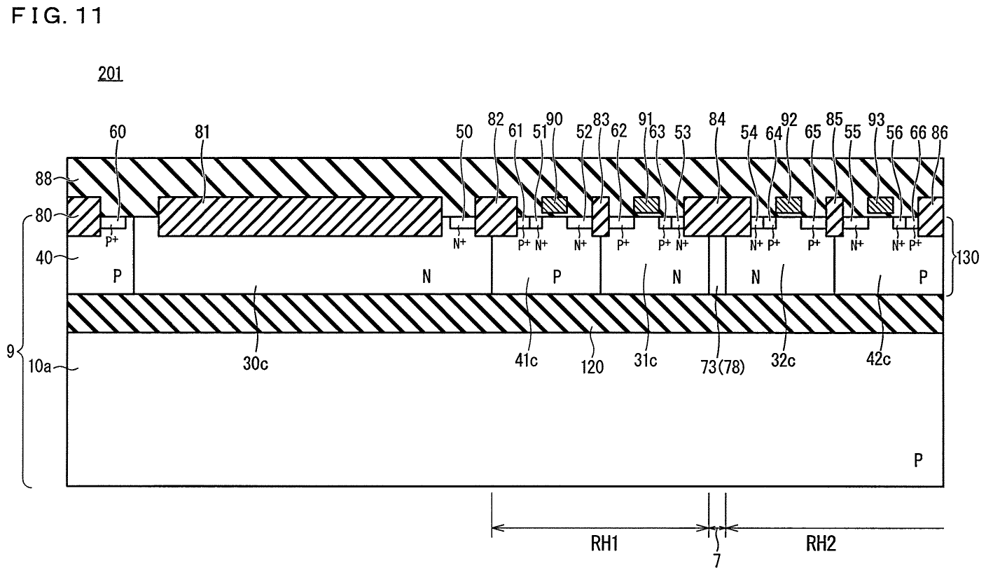

FIG. 11 is a cross-sectional view schematically illustrating a cross-sectional structure of a semiconductor device 201 as a first aspect of the fourth preferred embodiment. FIG. 11 illustrates a cross-sectional structure corresponding to the A-A cross section of FIG. 1. Note that a planar configuration and a circuit configuration of the semiconductor device 201 are similar to the configurations illustrated in FIGS. 1 and 2.

Hereinafter, points common to those of the semiconductor device 101 of the first aspect of the first preferred embodiment illustrated in FIG. 3 will be denoted by the same reference signs, description thereof will be omitted as appropriate, and characteristic points of the semiconductor device 201 of the first aspect of the fourth preferred embodiment will be mainly described.

In the semiconductor device 201, an SOI substrate 9 generally called an SOI wafer is adopted as a semiconductor substrate, instead of the P-type substrate 10 of the semiconductor device 101. The SOI substrate 9 has a laminate structure of a support substrate 10a, a buried oxide film 120, and an SOI layer 130, and the uppermost layer of the SOI substrate 9 is the SOI layer 130. In FIG. 11, a conductivity type of the support substrate 10a is a P type, but may be an N type. The SOI layer 130, which is a silicon active layer, is configured as, for example, the N type.

As illustrated in FIG. 11, the first and second high-side circuit regions RH1 and RH2 are provided in the SOI layer 130. As illustrated in FIG. 11, an N-type diffusion layer 30c and the P-type diffusion layer 40 are provided in the SOI layer 130 as first isolation regions for isolating the high-side circuit region RH and the low-side circuit region RL. The P-type diffusion layer 40 is provided so as to surround the high-side circuit region RH in plan view. The N-type diffusion layer 30c satisfies a RESURF condition. Similarly to the N-type diffusion layer 30a, the N⁺ diffusion layer 50 is provided in a surface of the N-type diffusion layer 30c.

An N-type diffusion layer 31c is provided in the SOI layer 130 in the first high-side circuit region RH1, and an N-type diffusion layer 32c is provided in the SOI layer 130 in the second high-side circuit region RH2.

The N-type diffusion layer 31c and the N-type diffusion layer 32c are formed at the same time. The N-type diffusion layer 30c serves as a first isolation diffusion region, the N-type diffusion layer 31c serves as a first circuit diffusion region, and the N-type diffusion layer 32c serves as a second circuit diffusion region.

Constituent elements of the first high-side circuit CH1 are provided in upper layer portions of the N-type diffusion layer 31c and a P-type diffusion layer 41c, respectively, similarly to the N-type diffusion layer 31b and the P-type diffusion layer 41b of the semiconductor device 102 illustrated in FIG. 4, and constituent elements of the second high-side circuit CH2 are provided in upper layer portions of the N-type diffusion layer 32c and the P-type diffusion layer 42c, respectively, similarly to the N-type diffusion layer 32b and the P-type diffusion layer 42b of the semiconductor device 102 illustrated in FIG. 4.

In the SOI substrate 9 serving as the semiconductor substrate of the fourth preferred embodiment, a region where the first and second high-side circuits CH1 and CH2 are not provided serves as a circuit base region. The first high-side circuit CH1 is provided in the N-type diffusion layer 31c, in the P-type diffusion layer 41c, on the N-type diffusion layer 31c, and on the P-type diffusion layer 41c. The second high-side circuit CH2 is provided in the N-type diffusion layer 32c, in the P-type diffusion layer 42c, on the N-type diffusion layer 32c, and on the P-type diffusion layer 42c.

In the semiconductor device 201, the support substrate 10a and the buried oxide film 120 serve as circuit base regions. The P-type diffusion layer 40, the N-type diffusion layer 30c, the N-type diffusion layer 31c, the N-type diffusion layer 32c, the P-type diffusion layer 41c, and the P-type diffusion layer 42c are provided in the SOI layer 130, and are not provided in the support substrate 10a and the buried oxide film 120. Therefore, the support substrate 10a and the buried oxide film 120 serve as the circuit base regions.

Note that, in a case where a conductivity type of the SOI layer 130, which is the silicon active layer, is the N type, remaining regions after the P-type diffusion layer 40, the P-type diffusion layer 41c, and the P-type diffusion layer 42c are formed in the SOI layer 130 may be the N-type diffusion layer 30c, the N-type diffusion layer 31c, and the N-type diffusion layer 32c.

Note that the N⁺ diffusion layer 53 and the P⁺ diffusion layers 62 and 63 are selectively provided in a surface of the N-type diffusion layer 31c similarly to the N-type diffusion layers 31a, 31b, 33a, and 33b. In addition, the N⁺ diffusion layer 54 and the P⁺ diffusion layers 64 and 65 are selectively provided in a surface of the N-type diffusion layer 32c similarly to the N-type diffusion layers 32a, 32b, 34a, and 34b.

Note that the P⁺ diffusion layer 61 and the N⁺ diffusion layers 51 and 52 are selectively provided in a surface of the P-type diffusion layer 41c similarly to the P-type diffusion layers 41a and 41b. In addition, the P⁺ diffusion layer 66 and the N⁺ diffusion layers 55 and 56 are selectively provided in a surface of the P-type diffusion layer 42c similarly to the P-type diffusion layers 42a and 42b.

In the semiconductor device 201, an isolation trench 73 is provided in the isolation region 7. The isolation trench 73 is provided between the N-type diffusion layer 31c serving as the first circuit diffusion region and the N-type diffusion layer 32c serving as the second circuit diffusion region, and is provided such that the deepest portion reaches an upper surface of the buried oxide film 120.

The N-type diffusion layer 31c and the N-type diffusion layer 32c are electrically isolated by the isolation trench 73. The isolation trench 73 is formed as follows, for example.

After a provisional N-type diffusion layer is formed in a region, which includes the first and second high-side circuit regions RH1 and RH2 and the isolation region 7, in the SOI layer 130, the isolation trench 73 is formed in the isolation region 7 so as to reach the upper surface of the buried oxide film 120 from a surface of the SOI layer 130 including the provisional N-type diffusion layer. The provisional N-type diffusion layer is isolated between the first and second high-side circuit regions RH1 and RH2 by the isolation trench 73.

As a result, the provisional N-type diffusion layer remaining in the first high-side circuit region RH1 serves as the N-type diffusion layer 31c, and the provisional N-type diffusion layer remaining in the second high-side circuit region RH2 serves as the N-type diffusion layer 32c. Therefore, the N-type diffusion layer 31c and the N-type diffusion layer 32c are electrically isolated by the isolation trench 73.

The isolation trench 73 includes the buried insulating film 78 inside similarly to the isolation trenches 70 to 72 of the first and second preferred embodiments.

### (Effects)

The semiconductor device 201 as the first aspect of the fourth preferred embodiment has effects similar to those of the semiconductor device 101 as the first aspect of the first preferred embodiment, and further has the following unique effect.

Since the semiconductor device 201 as the first aspect of the fourth preferred embodiment is isolated into the SOI layer 130 and the support substrate 10a by the buried oxide film 120, which is a dielectric, in the depth direction, a leakage current between the first and second high-side circuit regions RH1 and RH2 can be further reduced.

Further, the semiconductor device 201 can suppress a parasitic operation between the first and second high-side circuit regions RH1 and RH2 by the isolation trench 73 that is provided to penetrate the SOI layer 130 and has the buried insulating film 78 inside.

### (Second Aspect)

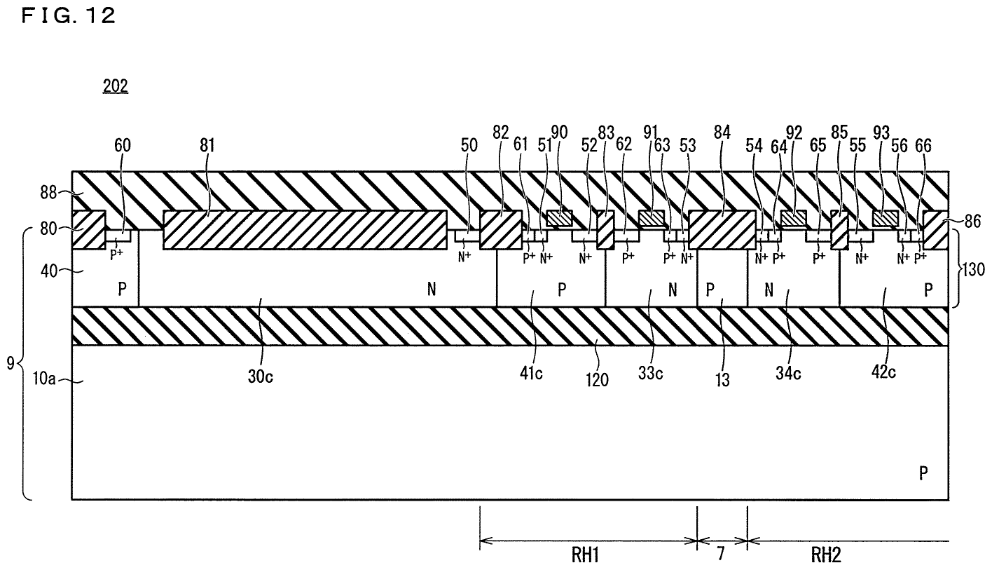

FIG. 12 is a cross-sectional view schematically illustrating a cross-sectional structure of a semiconductor device 202 as a second aspect of the fourth preferred embodiment. FIG. 12 illustrates a cross-sectional structure corresponding to the A-A cross section of FIG. 1. Note that a planar configuration and a circuit configuration of the semiconductor device 202 are similar to the configurations illustrated in FIGS. 1 and 2.

Hereinafter, points common to those of the semiconductor device 201 of the first aspect of the fourth preferred embodiment illustrated in FIG. 11 will be denoted by the same reference signs, description thereof will be omitted as appropriate, and characteristic points of the semiconductor device 202 of the second aspect of the fourth preferred embodiment will be mainly described.

In the semiconductor device 202, a P-type layer 13 is provided in place of the isolation trench 73 of the semiconductor device 201, an N-type diffusion layer 33c is provided in place of the N-type diffusion layer 31c, and an N-type diffusion layer 34c is provided in place of the N-type diffusion layer 32c.

Note that the N⁺ diffusion layer 53 and the P⁺ diffusion layers 62 and 63 are selectively provided in a surface of the N-type diffusion layer 33c similarly to the N-type diffusion layers 31a to 31c, 33a, and 33b. In addition, the N⁺ diffusion layer 54 and the P⁺ diffusion layers 64 and 65 are selectively provided in a surface of the N-type diffusion layer 34c similarly to the N-type diffusion layers 32a to 32c, 34a, and 34b.

As described above, the semiconductor device 202 as the second aspect of the fourth preferred embodiment is provided with the P-type layer 13, which serves as a second isolation diffusion region, as the isolation region 7. The P-type layer 13 is provided between the N-type diffusion layer 33c serving as a first circuit diffusion region and the N-type diffusion layer 34c serving as a second circuit diffusion region so as to be in contact with the N-type diffusion layers 33c and 34c. The P-type layer 13 functions as the second isolation diffusion region.

Hereinafter, a manufacturing method of the P-type layer 13 will be described. For example, a method of forming the P-type layer 13 in the N-type SOI layer 130 by ion implantation, diffusion processing, or the like using P-type impurities is used. At this time, it is necessary to provide the P-type layer 13 so as to penetrate the SOI layer 130 and reach the upper surface of the buried oxide film 120.

The semiconductor device 202 as the second aspect of the fourth preferred embodiment has effects similar to those of the semiconductor device 101 as the first aspect of the first preferred embodiment, and further has the following effect.

Since the semiconductor device 202 as the second aspect of the fourth preferred embodiment is isolated into the SOI layer 130 and the support substrate 10a by the buried oxide film 120, which is a dielectric, in the depth direction, a leakage current between the first and second high-side circuit regions RH1 and RH2 can be further reduced.

Further, the semiconductor device 202 includes the P-type layer 13 as the second isolation diffusion region between the N-type diffusion layer 33c serving as the first circuit diffusion region and the N-type diffusion layer 34c serving as the second circuit diffusion region. The P-type layer 13 is provided in contact with each of the N-type diffusion layers 33c and 34a.

Therefore, the semiconductor device 202 as the second aspect of the fourth preferred embodiment includes the P-type layer 13 in the isolation region 7 as the second isolation diffusion region, and thus, the first and second high-side circuit regions RH1 and RH2 can be electrically isolated from each other with a relatively simple structure, similarly to the semiconductor devices 107 and 108 of the third preferred embodiment.

### Others

In the present disclosure, the P type is indicated as the first conductivity type and the N type is indicated as the second conductivity type, but a modification in which the first conductivity type is the N type and the second conductivity type is the P type is also conceivable.

In the present disclosure, each of the preferred embodiments can be freely combined, and each of the preferred embodiments can be appropriately modified or omitted within the scope of the disclosure.

While the disclosure has been shown and described in detail, the foregoing description is in all aspects illustrative and not restrictive. It is therefore understood that numerous modifications and variations can be devised.

What is claimed is:

1. A semiconductor device comprising:
a semiconductor substrate;
a low-side circuit region that is provided in the semiconductor substrate and receives a first reference potential;
a high-side circuit region that is provided in the semiconductor substrate and receives a second reference potential different from the first reference potential; and
a first isolation region electrically isolating the low-side circuit region from the high-side circuit region,
wherein
the semiconductor substrate has a circuit base region in which the low-side circuit region and the high-side circuit region are not provided, and
the high-side circuit region includes first and second high-side circuit regions, a first high-side circuit is provided in the first high-side circuit region, a second high-side circuit is provided in the second high-side circuit region, the first high-side circuit operates at a first power supply voltage based on the second reference potential, the second high-side circuit operates at a second power supply voltage based on the second reference potential, and the first and second power supply voltages have different voltage values,
the semiconductor device further comprising:
a second isolation region electrically isolating the first high-side circuit region and the second high-side circuit region.

2. The semiconductor device according to claim 1, wherein
the circuit base region includes a substrate region of a first conductivity type,
the first isolation region includes a first isolation diffusion region of a second conductivity type, and the first isolation diffusion region is provided on the substrate region,
the first high-side circuit region includes a first circuit diffusion region of the second conductivity type, and the first circuit diffusion region is provided on the substrate region,
the second high-side circuit region includes a second circuit diffusion region of the second conductivity type, and the second circuit diffusion region is provided on the substrate region, and
the first and second circuit diffusion regions satisfy a diffusion region depth requirement, and the diffusion region depth requirement is a requirement that a formation depth of each of the first and second circuit diffusion regions is deeper than a formation depth of the first isolation diffusion region.

3. The semiconductor device according to claim 2, wherein
the second isolation region includes
an isolation trench that is provided between the first circuit diffusion region and the second circuit diffusion region and has a deepest portion reaching the substrate region, and
the isolation trench has a buried insulating film, configured to insulate and isolate the first and second high-side circuit regions from each other, inside.

4. The semiconductor device according to claim 3, wherein
the first circuit diffusion region includes a first buried diffusion layer of the second conductivity type selectively provided on the substrate region and a first surface diffusion layer of the second conductivity type selectively provided on the first buried diffusion layer, and
the second circuit diffusion region includes a second buried diffusion layer of the second conductivity type selectively provided on the substrate region and a second surface diffusion layer of the second conductivity type selectively provided on the second buried diffusion layer.

5. The semiconductor device according to claim 4, wherein
the isolation trench does not have a contact relationship with the first and second buried diffusion layers, and
the isolation trench satisfies a trench depth requirement, and the trench depth requirement is a requirement that a formation depth of the isolation trench is shallower than a formation depth of each of the first and second buried diffusion layers.

6. The semiconductor device according to claim 3, further comprising:
a trench bottom diffusion region of the first conductivity type provided in contact with the deepest portion of the isolation trench in a periphery of the deepest portion of the isolation trench in the substrate region.

7. The semiconductor device according to claim 2, wherein
the second isolation region includes a second isolation diffusion region of the first conductivity type provided between the first circuit diffusion region and the second circuit diffusion region in contact with the first and second circuit diffusion regions.

8. The semiconductor device according to claim 1, wherein
the semiconductor substrate includes an SOI substrate having a laminate structure of a support substrate, a buried oxide film, and an SOI layer,
the circuit base region includes the support substrate and the buried oxide film, and
the low-side circuit region, the high-side circuit region, and the second isolation region are provided in the SOI layer.

9. The semiconductor device according to claim 8, wherein
the second isolation region includes an isolation trench that is provided between the first high-side circuit region and the second high-side circuit region and has a deepest portion reaching the buried oxide film, and
the isolation trench has a buried insulating film, configured to insulate and isolate the first and second high-side circuit regions from each other, inside.

10. The semiconductor device according to claim 8, wherein
the first high-side circuit region includes a first circuit diffusion region of a second conductivity type, and the first circuit diffusion region is provided in the SOI layer,
the second high-side circuit region includes a second circuit diffusion region of the second conductivity type, and the second circuit diffusion region is provided in the SOI layer, and
the second isolation region includes a second isolation diffusion region of a first conductivity type provided between the first circuit diffusion region and the second circuit diffusion region in contact with the first and second circuit diffusion regions.

11. The semiconductor device according to claim 4, further comprising:
a trench bottom diffusion region of the first conductivity type provided in contact with the deepest portion of the isolation trench in a periphery of the deepest portion of the isolation trench in the substrate region.

12. The semiconductor device according to claim 5, further comprising:
a trench bottom diffusion region of the first conductivity type provided in contact with the deepest portion of the isolation trench in a periphery of the deepest portion of the isolation trench in the substrate region.
